(19) United States
(12) Patent Application Publication
(10) Pub. No.: US 2018/0319092 A1
(43) Pub. Date: Nov. 8, 2018

(54) CENTRIFUGAL GLUE INJECTION SYSTEM AND METHOD THEREOF

(71) Applicant: Primax Electronics Ltd., Taipei (TW)

(72) Inventor: Yuan-Lin Xiang, Taipei (TW)

(21) Appl. No.: 15/790,395

(22) Filed: Oct. 23, 2017

(30) Foreign Application Priority Data
May 8, 2017 (CN) 201710317596.1

(51) Int. Cl. B29C 65/48; H05K 5/00; B29C 65/52; B04B 5/00

(52) U.S. Cl. CPC B29C 65/4845; H05K 5/0017; B29L 2031/34; B04B 5/00; B29C 65/524

(57) ABSTRACT

A centrifugal glue injection system includes a transparent glue storage unit, a fixture and a centrifugal device. The transparent glue storage unit includes a transparent glue container corresponding to a glue-injecting hole of an electronic assembly. The transparent glue container stores UV curable glue. The fixture clamps and fixes the electronic assembly and the transparent glue container. The centrifugal device includes a rotating module, a motor and an UV light module. The fixture is carried on the rotating module. After the UV light module irradiates UV light on the transparent glue container for a predetermined time period, the motor is activated to drive rotation of the rotating module. During a centrifuging process, the UV curable glue in the transparent glue container is filled into the electronic assembly through the glue-injecting hole in response to a centrifugal force.

### FIELD OF THE INVENTION

The present invention relates to a field of a glue injection device, and more particularly to a glue injection system and a glue injection method for gluing an electronic assembly.

### BACKGROUND OF THE INVENTION

With the advances of electronic industries, electronic assemblies of electronic devices are developed toward miniaturization. While an electronic device or an electronic assembly is packaged through glue, it is necessary to precisely fill the glue into a tiny gap in the electronic device or the electronic assembly. However, the conventional method of using the glue to package the electronic device or the electronic assembly still has some drawbacks. For example, if the amount of the glue is improperly controlled, an excessive glue problem or a starved glue problem possibly occurs. Moreover, if the glue is cured earlier, a glue blockage problem or a bubble generation problem occurs.

For avoiding the glue blockage problem or the bubble generation problem, China Patent Publication No. CN102921598A disclosed a glue injection machine. The glue injection machine comprises a glue injection fixing bar and an article fixing mechanism. The article fixing mechanism is installed on a rotating platform. An article to be glued in fixed by the article fixing mechanism. Moreover, a glue-injecting hole of the article is aligned with a rotating shaft of the rotating platform through the article fixing mechanism. After the rotating platform is activated, the article is rotated relative to a center of the glue-injecting hole, which is a fixed position. While the article is rotated, a glue injection action is performed. After the glue is introduced into the article through the glue-injecting hole, the glue is diffused to the inner periphery of the article in response to a centrifugal force because the density of the glue is larger than the density of the air. Moreover, the air is automatically expelled in response to a centrifugal action. The filled glue is gradually collected from the inner periphery of the article to the rotating center. In such way, the bubble generation in the glue is avoided, and the filled glue is uniformly distributed within the article.

The conventional glue injection technology can avoid the bubble generation problem and uniformly distribute the glue. However, the conventional glue injection technology still has some drawbacks. For example, during the process of injecting the glue, the glue-injecting hole of the article has to be previously aligned with the rotating shaft of the rotating platform. Moreover, the glue injection machine is only capable of processing one article at a time. In other words, the conventional glue injection technology is time-consuming and labor-intensive. Since the fabricating process of the product is very complicated, the efficiency of fabricating the product is low. Moreover, after the glue injection process is completed, the portion of the glue distributed to the glue-injecting hole is sunken because the article is rotated relative to the center of the glue-injecting hole. Moreover, in case that an UV-curable glue is used, the conventional glue injection technology is not feasible because the transparence of the electronic device or the electronic assembly is not good enough for the UV light to pass through.

Therefore, there is a need of providing a glue injection system and a glue injection method for injecting light-curable glue into an electronic device or an electronic assembly in order to fix and glue the electronic device or the electronic assembly. Moreover, the glue injection system and the glue injection method can avoid the bubble generation problem and uniformly distribute the glue.

### SUMMARY OF THE INVENTION

In accordance with an aspect of the present invention, there is provided a centrifugal glue injection system for filling UV curable glue into an electronic assembly having a glue-injecting hole. The centrifugal glue injection system includes a transparent glue storage unit, a fixture and a centrifugal device. The transparent glue storage unit includes a transparent glue container corresponding to the glue-injecting hole. The UV curable glue is stored in the transparent glue container. The fixture clamps and fixes the electronic assembly and the transparent glue container. The centrifugal device includes a rotating module, a motor and an UV light module. The fixture is carried on the rotating module. After the UV light module irradiates UV light on the transparent glue container for a predetermined time period, the motor is activated to drive rotation of the rotating module, so that the fixture is subjected to a centrifuging process. During the centrifuging process, the UV curable glue in the transparent glue container is filled into the electronic assembly through the glue-injecting hole in response to a centrifugal force.

In an embodiment, the electronic assembly includes at least one vent, wherein during the centrifuging step, gases in the electronic assembly or bubbles in the UV curable glue are ejected out through the at least one vent.

In an embodiment, the transparent glue storage unit includes a first glue storage part and a second glue storage part, and the transparent glue container is defined between the first glue storage part and the second glue storage part.

In an embodiment, the transparent glue storage unit further includes a first attaching part and a second attaching part. The first attaching part and the second attaching part are attached on the electronic assembly, so that the transparent glue container is fixed at a position near the glue-injecting hole.

In an embodiment, the transparent glue storage unit is made of polyethylene terephthalate.

In an embodiment, the fixture includes a first clamping part and a second clamping part.

In an embodiment, the first clamping part includes a light-transmissible zone, and the transparent glue container is aligned with the light-transmissible zone. The UV light from the UV light module is irradiated on the transparent glue container through the light-transmissible zone.

In an embodiment, the second clamping part includes a light-transmissible zone, and the transparent glue container is aligned with the light-transmissible zone. The UV light from the UV light module is irradiated on the transparent glue container through the light-transmissible zone.

In an embodiment, a radiant energy density of the UV light from the UV light module within the predetermined time period is 1500 mJ/cm².

In an embodiment, the rotating module includes at least one fixing shaft, and the fixture includes a fixture hole. The at least one fixing shaft is penetrated through the fixture hole, so that the fixture is carried on the rotating module.

In an embodiment, the rotating module further includes at least one recess. The fixture is accommodated within the at least one recess, so that the fixture is carried on the rotating module.

In an embodiment, a centrifugal speed in the centrifuging step is 5000 rpm.

In an embodiment, the centrifugal device further includes a vacuum pipe. After gases within the centrifugal device are evacuated through the vacuum pipe, an inner portion of the centrifugal device is in a vacuum condition.

In an embodiment, when the inner portion of the centrifugal device is in the vacuum condition, a vacuum degree is lower than or equal to 400 Pa.

In accordance with another aspect of the present invention, there is provided a centrifugal glue injection method for filling UV curable glue into an electronic assembly having a glue-injecting hole. The centrifugal glue injection method includes the following steps. Firstly, a transparent glue container is formed at a position corresponding to the glue-injecting hole of the electronic assembly. Then, the UV curable glue is filled into the transparent glue container. Then, a fixture is used for clamping and fixing the electronic assembly and the transparent glue container. Then, UV light is irradiated on the transparent glue container for a predetermined time period. Then, a centrifuging process is performed on the fixture. Consequently, the UV curable glue in the transparent glue container is filled into the electronic assembly through the glue-injecting hole.

In an embodiment, a radiant energy density of the UV light in the step (d), is 1500 mJ/cm².

In an embodiment, the UV light is irradiated on the transparent glue container in a vacuum condition in the step (d).

In an embodiment, a vacuum degree in the vacuum condition is lower than or equal to 400 Pa.

In an embodiment, the centrifuging process is performed in a vacuum condition in the step (e).

In an embodiment, a vacuum degree in the vacuum condition is lower than or equal to 400 Pa.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic block diagram illustrating the architecture of a centrifugal glue injection system according to an embodiment of the present invention;

FIG. 2A is a schematic top view illustrating an electronic assembly to be glued according to an embodiment of the present invention;

FIG. 2B is a schematic cross-sectional view illustrating the electronic assembly to be glued according to an embodiment of the present invention;

FIG. 2C is a schematic perspective view illustrating the electronic assembly to be glued according to an embodiment of the present invention;

FIG. 2D is an enlarged fragmentary view illustrating the circumscribed zone of FIG. 2C;

FIG. 3A is a schematic view illustrating the transparent glue storage unit of the centrifugal glue injection system according to the embodiment of the present invention;

FIG. 3B is a schematic cross-sectional view illustrating the transparent glue storage unit according to the embodiment of the present invention;

FIG. 3C is a schematic perspective view illustrating the transparent glue storage unit according to the embodiment of the present invention;

FIG. 3D is an enlarged fragmentary view illustrating the circumscribed zone of FIG. 3C;

FIG. 4A is a schematic cross-sectional view illustrating a combination of the transparent glue storage unit and the electronic assembly according to the embodiment of the present invention;

FIG. 4B is a schematic perspective view illustrating a combination of the transparent glue storage unit and the electronic assembly according to the embodiment of the present invention;

FIG. 5A is a schematic exploded view illustrating a fixture for fixing the combination of the transparent glue storage unit and the electronic assembly according to a first embodiment of the present invention;

FIG. 5B is a schematic assembled view illustrating the fixture according to the first embodiment of the present invention;

FIG. 6A is a schematic cross-sectional view illustrating a centrifugal device according to a first embodiment of the present invention;

FIG. 6B is a schematic perspective view illustrating the centrifugal device according to the first embodiment of the present invention;

FIG. 7A is a schematic exploded view illustrating a fixture for fixing the combination of the transparent glue storage unit and the electronic assembly according to a second embodiment of the present invention;

FIG. 7B is a schematic assembled view illustrating the fixture according to the second embodiment of the present invention;

FIG. 8A is a schematic cross-sectional view illustrating a centrifugal device according to a second embodiment of the present invention;

FIG. 8B is a schematic perspective view illustrating the centrifugal device according to the second embodiment of the present invention; and

FIG. 9 is a flowchart illustrating a centrifugal glue injection method according to an embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

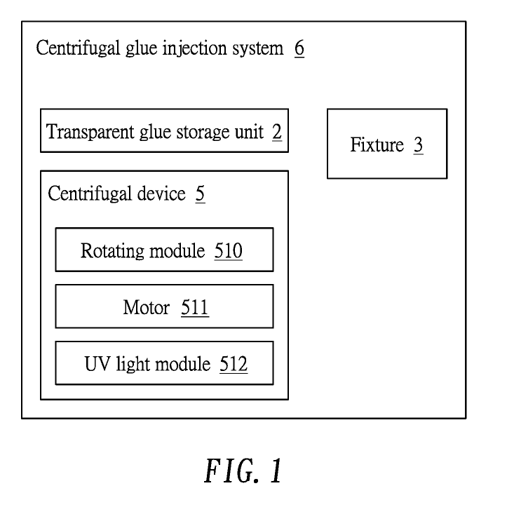

FIG. 1 is a schematic block diagram illustrating the architecture of a centrifugal glue injection system according to an embodiment of the present invention. As shown in FIG. 1, the centrifugal glue injection system 6 comprises a transparent glue storage unit 2, a centrifugal device 5 and a fixture 3. The transparent glue storage unit 2 is used for storing UV curable glue. The centrifugal device 5 comprises a rotating module 510, a motor 511 and an UV light module 512. Firstly, an electronic assembly to be glued is clamped by the fixture 3. Then, the UV light module 512 generates UV light to irradiate the UV curable glue. Consequently, the UV curable glue is pre-excited. Before the UV curable glue starts to be cured, the UV curable glue is filled into the electronic device or the electronic assembly that is ready to be glued.

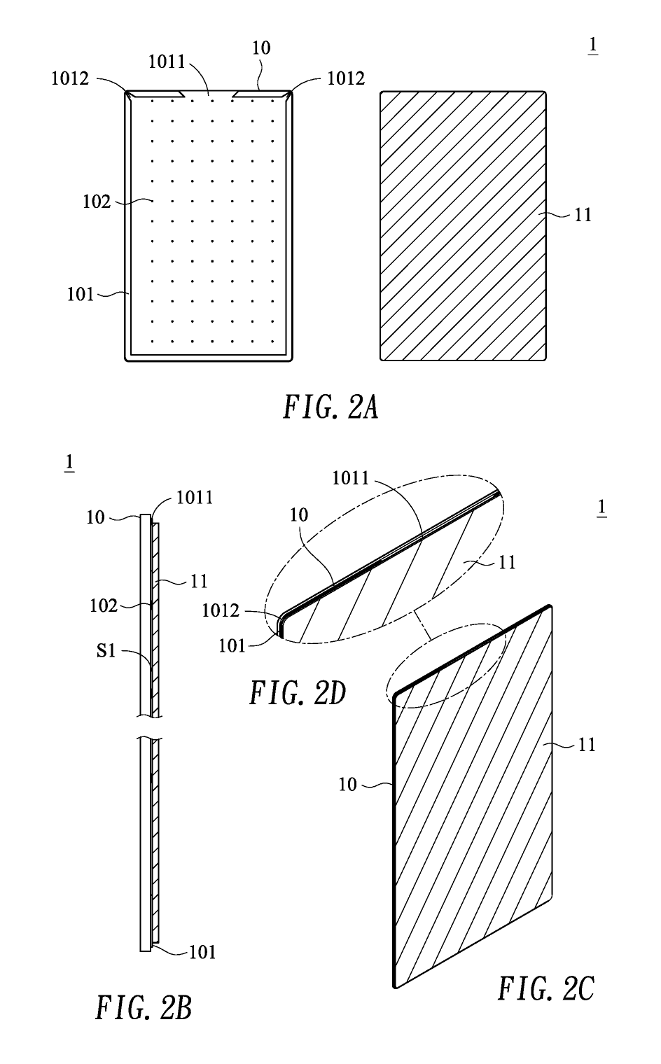

FIG. 2A is a schematic top view illustrating an electronic assembly to be glued according to an embodiment of the present invention. For example, the electronic assembly 1 is a touch panel assembly. The electronic assembly 1 comprises a glass plate 10 and a printed circuit board assembly (PCBA) 11. A frame 101 made of pressure sensitive adhesive (PSA) is formed on four lateral sides of a first surface of the glass plate 10. A glue-injecting hole 1011 is formed in a specified side of the frame 101. The UV curable glue can be injected to the electronic assembly 1 through the glue-injecting hole 1011. A vent 1012 is formed between the specified side of the frame 101 and an adjacent side of the frame 101. Another vent 1012 is formed between the specified side of the frame 101 and another adjacent side of the frame 101. Generally, gases are possibly generated in the electronic assembly 1 or bubbles are possibly generated in the UV curable glue during the process of filling the UV curable glue. The gases or bubbles are ejected to surroundings through the vents 1012. On the same side with the frame 101, the glass plate 10 is further equipped with plural dot spacers 102 according to a stencil printing technology. In an embodiment, the dot spacers 102 are made of UV curable glue.

Please refer to FIGS. 2B and 2C. FIG. 2B is a schematic cross-sectional view illustrating the electronic assembly to be glued according to an embodiment of the present invention. FIG. 2C is a schematic perspective view illustrating the electronic assembly to be glued according to an embodiment of the present invention. FIG. 2D is an enlarged fragmentary view illustrating the circumscribed zone of FIG. 2C. As shown in FIG. 2B, the printed circuit board assembly 11 and the first surface of the glass plate 10 with the frame 101 are attached on through the stickiness of the pressure sensitive adhesive of the frame 101. After the printed circuit board assembly 11 and the glass plate 10 are attached on each other, a glue-filling space S1 is defined between the glass plate 10 and the printed circuit board assembly 11. As shown in FIGS. 2C and 2D, the glue-injecting hole 1011 and the vents 1012 are located at an edge of the frame 101.

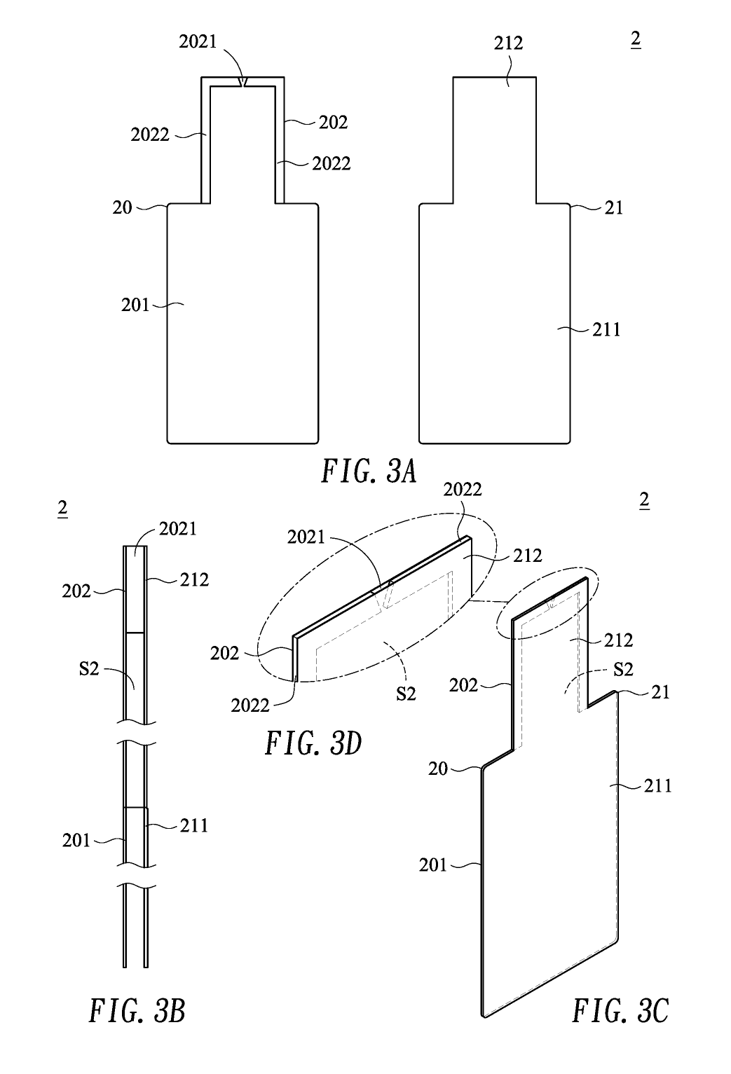

FIG. 3A is a schematic view illustrating the transparent glue storage unit of the centrifugal glue injection system according to the embodiment of the present invention. The transparent glue storage unit is made of polyethylene terephthalate (PET). As shown in FIG. 3A, the transparent glue storage unit 2 comprises a first casing 20 and a second casing 21. The first casing 20 comprises a first attaching part 201 and a first glue storage part 202. The second casing 21 comprises a second attaching part 211 and a second glue storage part 212. A raised structure 2022 is formed on three edges of the first glue storage part 202. Moreover, a glue-filling hole 2021 is formed in one side of the raised structure 2022. The edge of the first glue storage part 202 opposed to the glue-filling hole 2021 is not equipped with any raised structure 2022.

Please refer to FIGS. 3B and 3C. FIG. 3B is a schematic cross-sectional view illustrating the transparent glue storage unit according to the embodiment of the present invention. FIG. 3C is a schematic perspective view illustrating the transparent glue storage unit according to the embodiment of the present invention. FIG. 3D is an enlarged fragmentary view illustrating the circumscribed zone of FIG. 3C. As shown in FIG. 3B, the second casing 21 and the surface of the first casing 20 with the raised structure 2022 are combined together through a binder. Consequently, a transparent glue container S2 is defined between the first glue storage part 202 and the second glue storage part 212. As shown in FIGS. 3C and 3D, the glue-filling hole 2021 is located beside the transparent glue container S2. Moreover, the glue-filling hole 2021 is in communication with the transparent glue container S2.

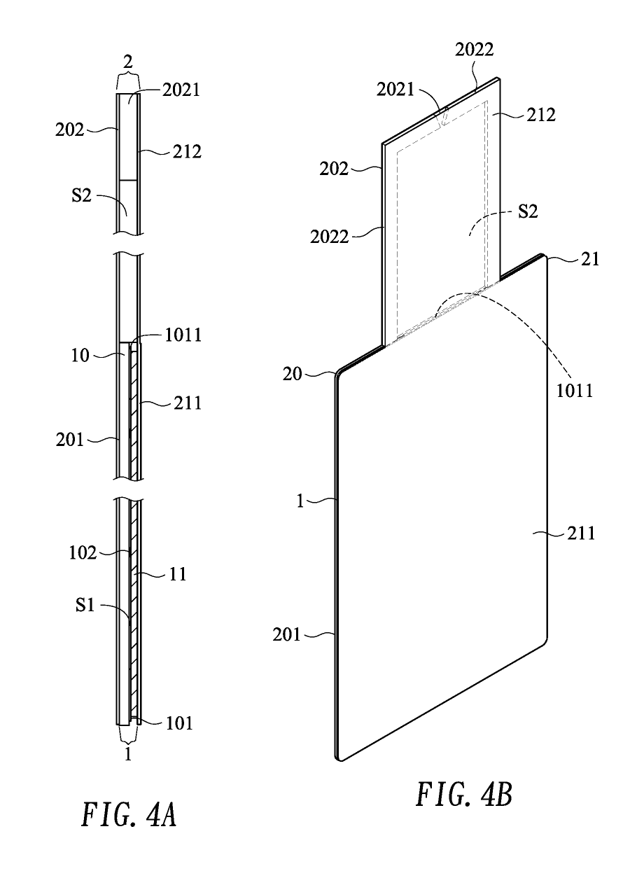

Please refer to FIGS. 4A and 4B. FIG. 4A is a schematic cross-sectional view illustrating a combination of the transparent glue storage unit and the electronic assembly according to the embodiment of the present invention. FIG. 4B is a schematic perspective view illustrating a combination of the transparent glue storage unit and the electronic assembly according to the embodiment of the present invention. As shown in FIG. 4A, the first attaching part 201 or a second surface of the glass plate 10 without the frame 101 is coated with an ordinary binder. The ordinary binder has low adhesion capacity for temporarily attaching two parts on each other. The first attaching part 201 and the glass plate 10 are attached on each other through the ordinary binder. Moreover, the second attaching part 211 or a surface of the printed circuit board assembly 11 not attached with the frame 101 is coated with the ordinary binder. The second attaching part 211 and the printed circuit board assembly 11 are attached with each other through the binder. As shown in FIG. 4A, the transparent glue container S2 is located beside the glue-injecting hole 1011 of the electronic assembly 1. The transparent glue container S2 is in communication with the glue-filling space S1 through the glue-injecting hole 1011. As shown in FIG. 4B, the edge of the first glue storage part 202 without the raised structure 2022 is located beside and contacted with the top edge of the electronic assembly 1. Moreover, the glue-filling hole 2021 is in communication with the transparent glue container S2. As shown in FIG. 4A, the transparent glue container S2 is in communication with the glue-filling space S1 through the glue-injecting hole 1011. In this embodiment, the transparent glue storage unit is composed of two components. It is noted that the examples of the transparent glue storage unit are not restricted. For example, the material, shape or structure of the transparent glue storage unit may be varied according to the type of the electronic device or the electronic assembly to be glued.

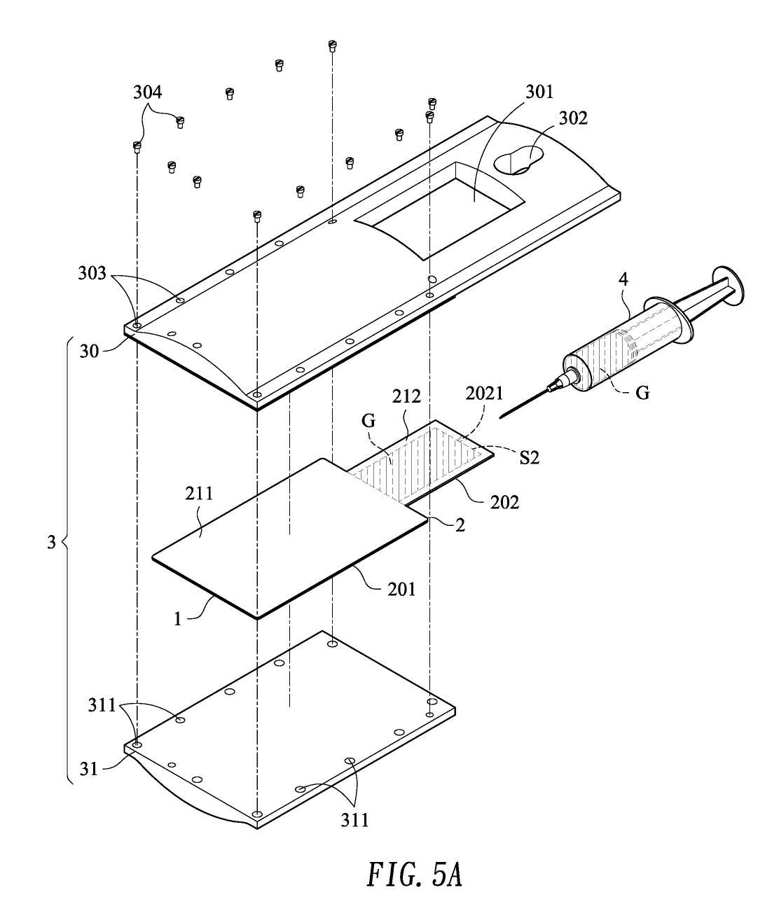

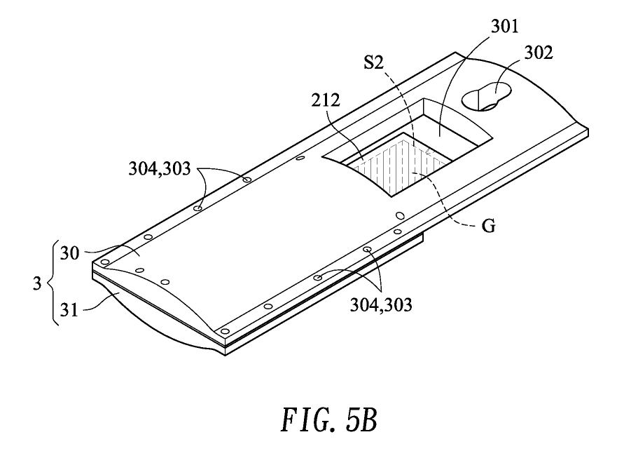

Please refer to FIGS. 5A and 5B. FIG. 5A is a schematic exploded view illustrating a fixture for fixing the combination of the transparent glue storage unit and the electronic assembly according to a first embodiment of the present invention. FIG. 5B is a schematic assembled view illustrating the fixture according to the first embodiment of the present invention. As shown in FIG. 5A, the fixture 3 comprises a first clamping part 30 and a second clamping part 31. The first clamping part 30 comprises a light-transmissible zone 301, a fixture hole 302, plural first screw holes 303 and plural screws 304. The second clamping part 31 comprises plural second screw holes 311 corresponding to the plural first screw holes 303. After the screws 304 are penetrated through the corresponding first screw holes 303 and tightened into the corresponding second screw holes 311, the combination of the transparent glue storage unit 2 and the electronic assembly 1 is clamped between the first clamping part 30 and the second clamping part 31 of the fixture 3. After the combination of the transparent glue storage unit 2 and the electronic assembly 1 is clamped by the fixture 3, the UV curable glue G is injected through the glue-filling hole 2021 by a syringe 4 and filled into the transparent glue container S2. Please refer to FIG. 5B. After the screws 304 are tightened into the corresponding second screw holes 311, the combination of the transparent glue storage unit 2 and the electronic assembly 1 is securely clamped and fixed by the first clamping part 30 and the second clamping part 31. Meanwhile, the transparent glue container S2 is aligned with the light-transmissible zone 301. The light-transmissible zone 301 and the fixture hole 302 of the fixture 3 are formed in the first clamping part 30 or the second clamping part 31. The light-transmissible zone 301 and the fixture hole 302 are not restrainedly formed in the first clamping part 30. In the above embodiment, the fixture 3 is assembled through the screws 304. It is noted that the means for assembling the fixture 3 are not restricted. For example, two components of the fixture may be assembled with each other through an engaging means, an adhering means or any other coupling means. In the above embodiment, the fixture is composed of two components. It is noted that the examples of the fixture are not restricted. For example, the shape or structure of the fixture may be varied according to the type of the electronic device or the electronic assembly and the corresponding transparent glue storage unit.

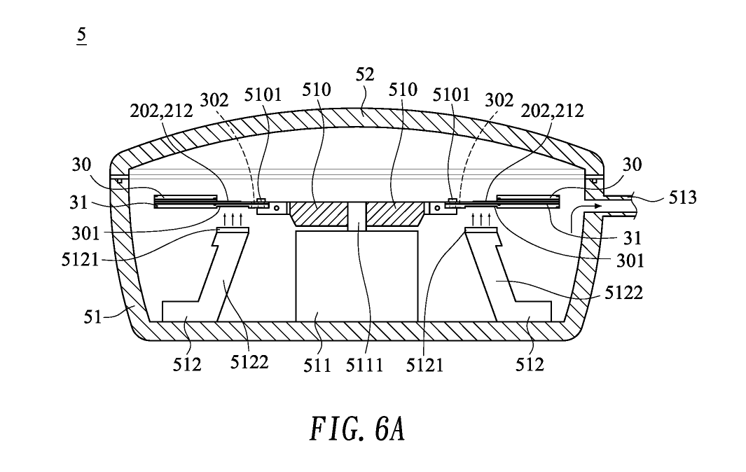

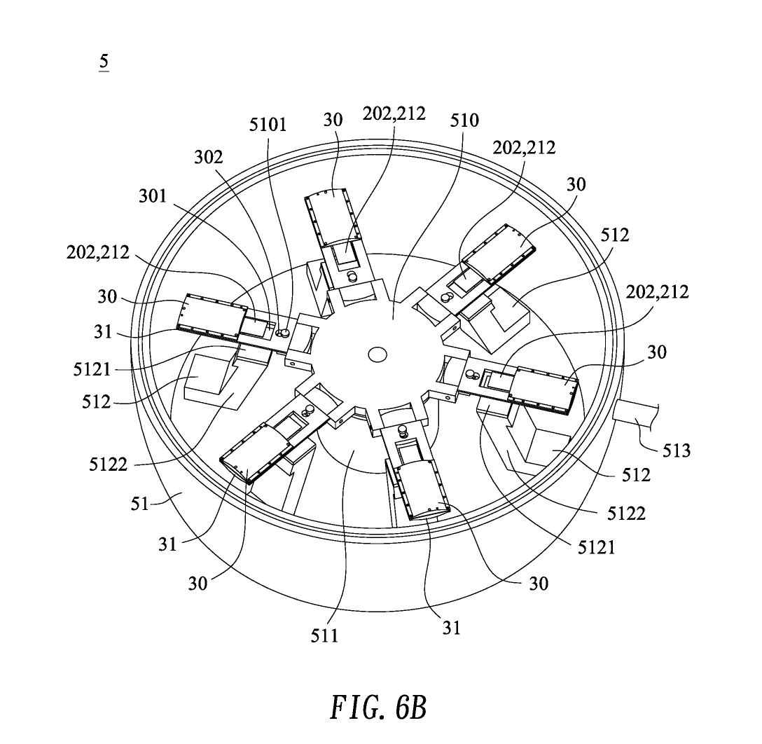

Please refer to FIGS. 6A and 6B. FIG. 6A is a schematic cross-sectional view illustrating a centrifugal device according to a first embodiment of the present invention. FIG. 6B is a schematic perspective view illustrating the centrifugal device according to the first embodiment of the present invention. As shown in FIG. 6A, the centrifugal device 5 comprises a main body 51 and a top cover 52. After the main body 51 is covered by the top cover 52, the main body 51 is sealed by the top cover 52. Consequently, the inner portion of the centrifugal device 5 is sealed from the surroundings. Moreover, the rotating module 510, the motor 511, the UV light module 512 and a vacuum pipe 513 are disposed within the main body 51. The motor 511 comprises a driving shaft 5111. The driving shaft 5111 is connected with the rotating module 510. When the motor 511 is activated, the rotating module 510 is driven to rotate through the driving shaft 5111. The rotating module 510 comprises at least one fixing shaft 5101. As shown in FIG. 5B, the fixing shaft 5101 is penetrated through the fixture hole 302 of the corresponding fixture 3. The fixture 3 is carried on the rotating module 510 through the fixing shaft 5101. The UV light module 512 comprises an UV light generation unit 5121 and a bracket 5122. The UV light module 512 is located under the corresponding fixture 3. The UV light generation unit 5121 emits UV light. As shown in FIGS. 5A and 5B, the UV light is irradiated on the UV curable glue G within the transparent glue container S2 through the light-transmissible zone 301 of the fixture 3. Each fixture 3 is aligned with one underlying UV light module 512. By controlling and adjusting the illuminance and the irradiating time of the UV light from the UV light generation unit 5121, the UV curable glue G within the transparent glue container S2 corresponding to each fixture 3 receives stable UV light exposure. The vacuum pipe 513 is connected with a vacuum pump (not shown). When the vacuum pump is activated, the gas within the centrifugal device 5 is evacuated through the vacuum pipe 513. Consequently, the inner portion of the centrifugal device 5 is in a vacuum condition. Under this circumstance, the gases contained in the electronic assembly 1 that is clamped by the fixture 3 and the bubbles contained in the UV curable glue G are reduced. Preferably, when the inner portion of the centrifugal device 5 is in the vacuum condition, the vacuum degree is lower than or equal to 400 Pa.

Before the rotating module 510 is rotated to centrifuge the carried fixture 3, the UV light from the UV light module 512 irradiated on the UV curable glue G within the transparent glue container S2 through the light-transmissible zone 301 of the electronic assembly 1 for a predetermined time period. Consequently, the UV curable glue G is pre-excited. In an embodiment, the predetermined time period is 3 seconds, and the illuminance of the UV light generation unit 5121 is 500 mW/cm². In other words, the radiant energy density of the UV light is 1500 mJ/cm². It is noted that the radiant energy density of the UV light is not restricted. For example, the radiant energy density of the UV light may be varied according to the type and the volume of the UV curable glue.

After the pre-exciting process is completed, the UV curable glue G does not start to be cured. That is, the UV curable glue G is still in the liquid state. Then, the motor 511 of the centrifugal device 5 is activated to rotate the rotating module 510. Consequently, the fixture 3 carried on the rotating module 510 is centrifuged. In response to the centrifugal force, the UV curable glue G within the transparent glue container S2 is filled into the glue-filling space S1 of the electronic assembly 1 through the glue-injecting hole 1011 (see FIG. 4A). Preferably, the centrifugal speed in the centrifuging step is 5000 rpm. It is noted that the centrifugal speed is not restricted. For example, the centrifugal speed may be varied according to the time period of filling the UV curable glue.

While the UV curable glue G is filled into the glue-filling space S1 in response to the centrifugal force, the gases in the electronic assembly 1 are ejected to surroundings through the vents 1012 (see FIG. 4B). Since the inner portion of the centrifugal device 5 is in the vacuum condition, the bubbles contained in the UV curable glue G within the glue-filling space S1 are also ejected to surroundings through the vents 1012. After the glue-filling space S1 is full of the UV curable glue G, the UV curable glue G is cured. Consequently, the glass plate 10 and the printed circuit board assembly 11 are combined together. After the fixture 3 and the transparent glue storage unit 2 are removed, the electronic assembly 1 glued through the UV curable glue G is obtained.

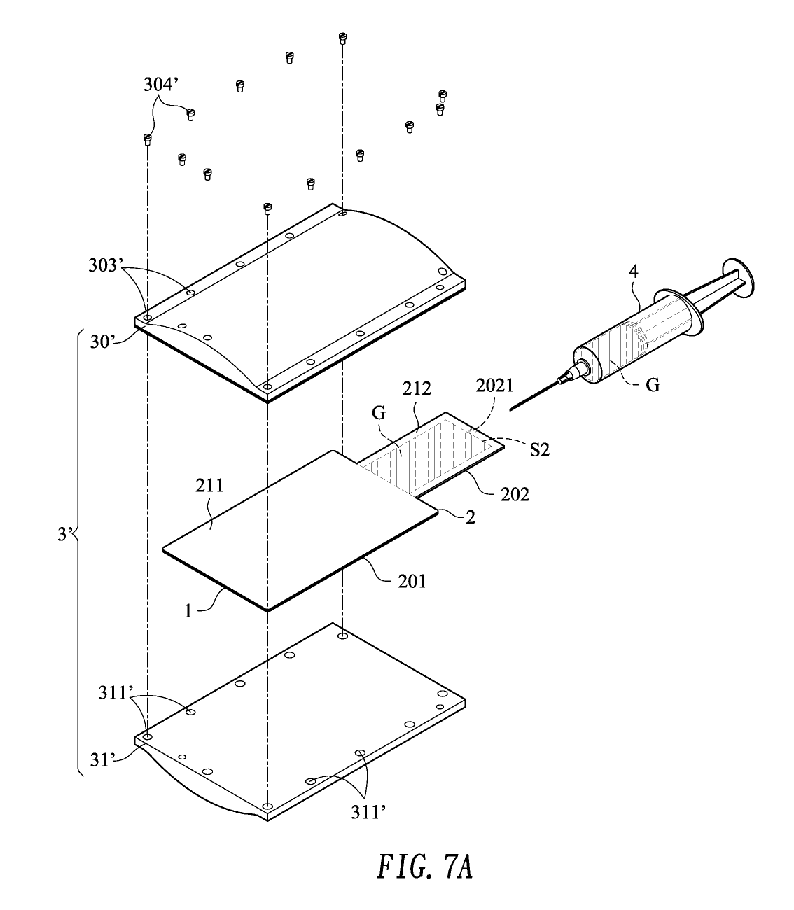

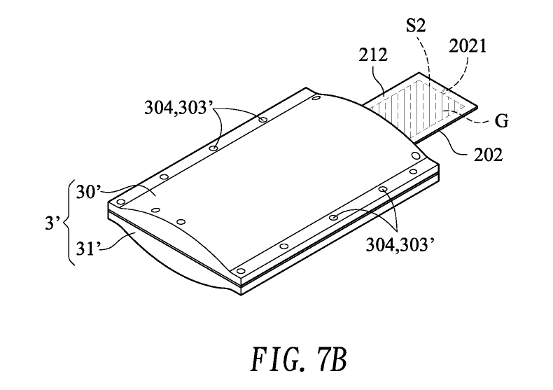

Please refer to FIGS. 7A and 7B. FIG. 7A is a schematic exploded view illustrating a fixture for fixing the combination of the transparent glue storage unit and the electronic assembly according to a second embodiment of the present invention. FIG. 7B is a schematic assembled view illustrating the fixture according to the second embodiment of the present invention. The electronic assembly 1, the transparent glue storage unit 2, the syringe 4 and the UV curable glue G of this embodiment are similar to those of FIGS. 5A and 5B. The following items are distinguished from FIGS. 5A and 5B, and are not redundantly described herein. For example, first clamping part 30′ of the fixture 3′ is not equipped with the light-transmissible zone 301 and the fixture hole 302. After the screws 304′ are penetrated through the corresponding first screw holes 303′ and tightened into the corresponding second screw holes 311′, the combination of the transparent glue storage unit 2 and the electronic assembly 1 is clamped between the first clamping part 30′ and the second clamping part 31′ of the fixture 3′.

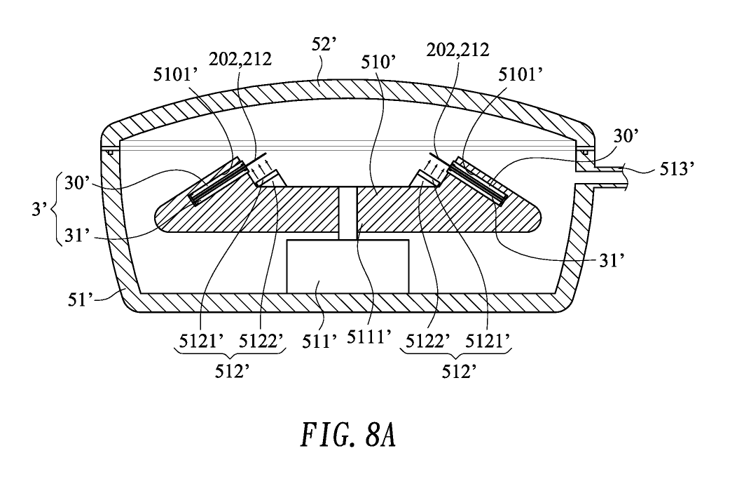

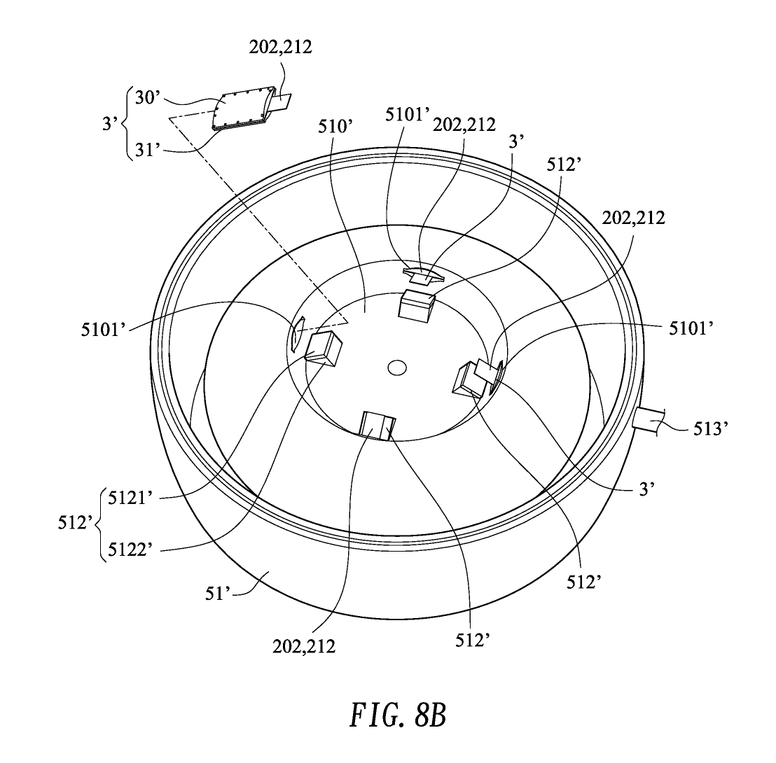

Please refer to FIGS. 8A and 8B. FIG. 8A is a schematic cross-sectional view illustrating a centrifugal device according to a second embodiment of the present invention. FIG. 8B is a schematic perspective view illustrating the centrifugal device according to the second embodiment of the present invention. The main body 51′, the top cover 52′, the rotating module 510′, the motor 511′, the UV light module 512′ and the vacuum pipe 513′ of the centrifugal device 5′ of this embodiment are similar to those of the corresponding components of FIGS. 6A and 6B, and are not redundantly described herein. In comparison with the above embodiment, the rotating module 510′ further comprises at least one recess 5101′ for accommodating the corresponding fixture 3′. When the fixture 3′ is accommodated within the recess 5101′, the fixture 3′ is carried on the rotating module 510′ and the first glue storage part 202 and the second glue storage part 212 of the transparent glue storage unit 2 are exposed outside the recess 5101′. Moreover, the UV light module 512′ is located at a surface of the rotating module 510′ corresponding to the recess 5101′. The UV light generation unit 5121′ is supported by the bracket 5122′. The UV light emitted by the UV light generation unit 5121′ travels toward the first glue storage part 202 and the second glue storage part 212 of the transparent glue storage unit 2. That is, as shown in FIG. 7B, the UV light emitted by the UV light generation unit 5121′ is irradiated on the UV curable glue G within the transparent glue container S2. Each fixture 3′ is aligned with one UV light module 512′. By controlling and adjusting the illuminance and the irradiating time of the UV light from the UV light generation unit 5121′, the UV curable glue G within the transparent glue container S2 corresponding to each fixture 3 receives stable UV light exposure.

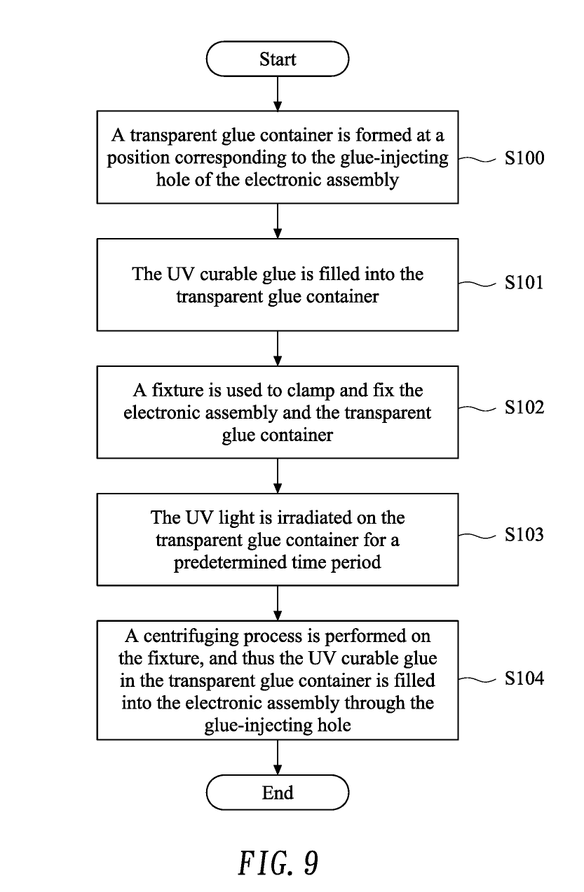

Please refer to FIGS. 4A, 5A, 6A and 9. FIG. 9 is a flowchart illustrating a centrifugal glue injection method according to an embodiment of the present invention. Firstly, a transparent glue container S2 at a position corresponding to a glue-injecting hole 1011 of an electronic assembly 1 (Step S100). In the step S100, the electronic assembly 1 comprises a glass plate 10, a printed circuit board assembly 11 and a glue-filling space S1. The glue-filling space S1 is defined between the glass plate 10 and the printed circuit board assembly 11. The transparent glue container S2 has a glue-filling hole 2021. The electronic assembly 1 has a glue-injecting hole 1011. The transparent glue container S2 is in communication with the glue-filling space S1 of the electronic assembly 1 through the glue-injecting hole 1011. Then, the UV curable glue G is filled into the transparent glue container S2 (Step S101). In the step S101, the UV curable glue G is injected through the glue-filling hole 2021 by a syringe 4 and filled into the transparent glue container S2.

Then, a fixture 3 is used to clamp and fix the electronic assembly 1 and the transparent glue container S2 (Step S102). In the step S102, the fixture 3 comprises a first clamping part 30 and a second clamping part 31. The first clamping part 30 comprises a light-transmissible zone 301, a fixture hole 302, plural first screw holes 303 and plural screws 304. The second clamping part 31 comprises plural second screw holes 311 corresponding to the plural first screw holes 303. After the screws 304 are penetrated through the corresponding first screw holes 303 and tightened into the corresponding second screw holes 311, the combination of the transparent glue storage unit 2 and the electronic assembly 1 is clamped between the first clamping part 30 and the second clamping part 31 of the fixture 3. Then, an UV light is irradiated on the transparent glue container S2 for a predetermined time period (Step S103). In the step S103, an UV light generation unit 5121 of an UV light module 512 emits the UV light. The UV light is irradiated on the UV curable glue G within the transparent glue container S2, which is supported by the fixture 3. By controlling and adjusting the illuminance and the irradiating time of the UV light from the UV light generation unit 5121, the UV curable glue G within the transparent glue container S2 corresponding to each fixture 3 receives stable UV light exposure. In an embodiment, the predetermined time period is 3 seconds, and the illuminance of the UV light generation unit 5121 is 500 mW/cm². In other words, the radiant energy density of the UV light is 1500 mJ/cm².

Then, a centrifuging process is performed on the fixture 3, so that the UV curable glue G in the transparent glue container S2 is filled into the electronic assembly 1 through the glue-injecting hole 1011 (Step S104). In the step S104, the fixture 3 is carried on the rotating module 510 of the centrifugal device 5. After the UV curable glue G is pre-excited, the UV curable glue G is not cured. That is, the UV curable glue G is still in the liquid state. Then, the motor 511 of the centrifugal device 5 is activated to rotate the rotating module 510. Consequently, the fixture 3 carried on the rotating module 510 is centrifuged. In response to the centrifugal force, the UV curable glue G within the transparent glue container S2 is filled into the glue-filling space S1 of the electronic assembly 1 through the glue-injecting hole 1011 of the electronic assembly 1. Preferably, the centrifugal speed in the centrifuging step is 5000 rpm. After the glue-filling space S1 is full of the UV curable glue G, the UV curable glue G starts to be cured. Consequently, the glass plate 10 and the printed circuit board assembly 11 are combined together. Moreover, the step S103 or the step S104 is performed in a vacuum condition. In the vacuum condition, the gases contained in the electronic assembly 1 or the bubbles contained in the UV curable glue G are reduced. Preferably, when the inner portion of the centrifugal device 5 is in the vacuum condition, the vacuum degree is lower than or equal to 400 Pa.

In the above embodiment, the centrifugal glue injection system is applied to a touch panel assembly. It is noted that the applications of the centrifugal glue injection system are not restricted. That is, the centrifugal glue injection system can be applied to any electronic device or any electronic assembly that needs to be filled with the UV curable glue. Moreover, the examples of the transparent glue storage unit, the fixture and the rotating module may be varied according to the structure and type of the electronic device or the electronic assembly. Moreover, the centrifugal glue injection system is suitable for filling glue to the transparent or opaque electronic device or electronic assembly.

In comparison with the conventional technologies, the centrifugal glue injection system and the centrifugal glue injection method of the present invention pre-excite the UV curable glue. Consequently, plural electronic assemblies can be filled with the glue at the same. Moreover, the technologies of the present invention are suitable for filling glue to the transparent or opaque electronic device or electronic assembly. The centrifugal glue injection of the present invention uses the centrifugal force to uniformly fill the UV curable glue to the electronic assembly. In the vacuum condition, the bubbles in the UV curable glue are effectively reduced. In other words, the technologies of the present invention are industrially valuable.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all modifications and similar structures.

What is claimed is:

1. A centrifugal glue injection system for filling UV curable glue into an electronic assembly having a glue-injecting hole, the centrifugal glue injection system comprising:
a transparent glue storage unit comprising a transparent glue container corresponding to the glue-injecting hole, wherein the UV curable glue is stored in the transparent glue container;
a fixture clamping and fixing the electronic assembly and the transparent glue container; and
a centrifugal device comprising a rotating module, a motor and an UV light module, wherein the fixture is carried on the rotating module,
wherein after the UV light module irradiates UV light on the transparent glue container for a predetermined time period, the motor is activated to drive rotation of the rotating module, so that the fixture is subjected to a centrifuging process, wherein during the centrifuging process, the UV curable glue in the transparent glue container is filled into the electronic assembly through the glue-injecting hole in response to a centrifugal force.

2. The centrifugal glue injection system according to claim 1, wherein the electronic assembly comprises at least one vent, wherein during the centrifuging step, gases in the electronic assembly or bubbles in the UV curable glue are ejected out through the at least one vent.

3. The centrifugal glue injection system according to claim 1, wherein the transparent glue storage unit comprises a first glue storage part and a second glue storage part, and the transparent glue container is defined between the first glue storage part and the second glue storage part.

4. The centrifugal glue injection system according to claim 3, wherein the transparent glue storage unit further comprises a first attaching part and a second attaching part, wherein the first attaching part and the second attaching part are attached on the electronic assembly, so that the transparent glue container is fixed at a position near the glue-injecting hole.

5. The centrifugal glue injection system according to claim 1, wherein the transparent glue storage unit is made of polyethylene terephthalate.

6. The centrifugal glue injection system according to claim 1, wherein the fixture comprises a first clamping part and a second clamping part.

7. The centrifugal glue injection system according to claim 6, wherein the first clamping part comprises a light-transmissible zone, and the transparent glue container is aligned with the light-transmissible zone, wherein the UV light from the UV light module is irradiated on the transparent glue container through the light-transmissible zone.

8. The centrifugal glue injection system according to claim 6, wherein the second clamping part comprises a light-transmissible zone, and the transparent glue container is aligned with the light-transmissible zone, wherein the UV light from the UV light module is irradiated on the transparent glue container through the light-transmissible zone.

9. The centrifugal glue injection system according to claim 1, wherein a radiant energy density of the UV light from the UV light module within the predetermined time period is 1500 mJ/cm².

10. The centrifugal glue injection system according to claim 1, wherein the rotating module comprises at least one fixing shaft, and the fixture comprises a fixture hole, wherein the at least one fixing shaft is penetrated through the fixture hole, so that the fixture is carried on the rotating module.

11. The centrifugal glue injection system according to claim 1, wherein the rotating module further comprises at least one recess, wherein the fixture is accommodated within the at least one recess, so that the fixture is carried on the rotating module.

12. The centrifugal glue injection system according to claim 1, wherein a centrifugal speed in the centrifuging step is 5000 rpm.

13. The centrifugal glue injection system according to claim 1, wherein the centrifugal device further comprises a vacuum pipe, wherein after gases within the centrifugal device are evacuated through the vacuum pipe, an inner portion of the centrifugal device is in a vacuum condition.

14. The centrifugal glue injection system according to claim 13, wherein when the inner portion of the centrifugal device is in the vacuum condition, a vacuum degree is lower than or equal to 400 Pa.

15. A centrifugal glue injection method for filling UV curable glue into an electronic assembly having a glue-injecting hole, the centrifugal glue injection method comprising steps of:
(a) forming a transparent glue container at a position corresponding to the glue-injecting hole of the electronic assembly;
(b) filling the UV curable glue into the transparent glue container;
(c) clamping and fixing the electronic assembly and the transparent glue container by using a fixture;
(d) irradiating UV light on the transparent glue container for a predetermined time period; and
(e) performing a centrifuging process on the fixture, so that the UV curable glue in the transparent glue container is filled into the electronic assembly through the glue-injecting hole.

16. The centrifugal glue injection method according to claim 15, wherein in the step (d), a radiant energy density of the UV light is 1500 mJ/cm².

17. The centrifugal glue injection method according to claim 15, wherein in the step (d), the UV light is irradiated on the transparent glue container in a vacuum condition.

18. The centrifugal glue injection method according to claim 17, wherein a vacuum degree in the vacuum condition is lower than or equal to 400 Pa.

19. The centrifugal glue injection method according to claim 15, wherein in the step (e), the centrifuging process is performed in a vacuum condition.

20. The centrifugal glue injection method according to claim 19, wherein a vacuum degree in the vacuum condition is lower than or equal to 400 Pa.
